(19) United States
(12) Patent Application Publication
(10) Pub. No.: US 2003/0090005 A1
(43) Pub. Date: May 15, 2003

(54) Chemical strengthening treatment unit for applying chemical strengthening treatment to glass substrates used in information recording media applications

(75) Inventor: Junichi Hashimoto, Osaka-Shi (JP)

Correspondence Address: CAESAR, RIVISE, BERNSTEIN,, COHEN & POKOTILOW, LTD., 12TH FLOOR, SEVEN PENN CENTER, 1635 MARKET STREET, PHILADELPHIA, PA, 19103-2212, US

(73) Assignee: Nippon Sheet Glass Co., Ltd., Osaka-shi (JP)

(21) Appl. No.: 10/288,077

(22) Filed: Nov. 5, 2002

(30) Foreign Application Priority Data
Nov. 9, 2001 (JP) 2001-345181

(51) Int. Cl. H01L 23/28

(52) U.S. Cl. 257/787

(57) ABSTRACT

A unit for applying chemical strengthening treatment to glass substrates for information recording media applications. The unit comprises a holder for holding a plurality of glass substrate and a tank which contains a molten solution of a prescribed salt. In the unit, the glass substrate is chemically strengthened by replacing a part of the ions in the glass substrates with the ions in said molten solution and having ion radius larger than that of the ions in the glass substrate. At least one of the holder and the tank is formed of a nickel alloy.

### BACKGROUND OF THE INVENTION

This invention relates to a unit for applying chemical strengthening treatment to glass substrates, which are used in information recording media applications. The information recording media include, for example, magnetic disks such as hard disks, optical magnetic disks, and optical disks.

In recent years, the progress in information technologies (IT) is remarkable. Various types of information recording media such as magnetic disks have been developed one after another. For glass substrates used in hard disks of hard disk drive (HDD) applications for example, higher surface smoothness and higher strength are required as the functions of electronic products improved. To meet such requirements, the surface of the glass substrates has been subjected to chemical strengthening treatment.

In this chemical strengthening treatment, generally more than one glass substrate is held in one holder. Then, the holders are immersed, in a state where they are contained in more than one cage, in a tank, which contains a heated molten solution of a salt used for chemical strengthening applications, such as potassium nitrate. At the time of immersion, ions such as sodium ions contained in the glass are replaced with ions such as potassium ions having a larger ion radius than that of sodium ions, whereby a compressive stress layer is formed on the surface of the glass substrates. The glass substrates are strengthened due to the formation of the compressive stress layer. The strengthened glass substrates are made into glass substrates for magnetic recording media applications through the later steps of precision polishing, rinsing and drying.

The tank, holders and cages which are kept contact with a molten salt are required to have a good performance, that is, to have good corrosion resistance and heat resistance, as well as a small thermal expansion coefficient. As the materials used for such equipment and capable of meeting these requirements, stainless alloys such as martensitic stainless steel and austenitic stainless steel are known.

In the stainless alloys such as martensitic stainless steel and austenitic stainless steel. However, iron and chromium contained therein can sometimes be oxidized to cause corrosion therein when they are kept in contact with a high temperature molten salt, such as potassium nitrate, for a long time. In that case, rust due to the corrosion is deposited on the surface of the glass substrates. When such a deposited matter cannot be removed by subsequent washing, it will cause the glass substrate to deteriorate.

When the equipments are formed from a stainless alloy, the iron content is eluted due to the welding heat from arc welding process for processing each piece of equipment. Accordingly, rust is likely to occur due to the elution of the iron content. In addition, while chemical strengthening treatment is usually performed for several hours at temperatures as high as 350 to 400° C., stainless alloys are not sufficiently heat resistant at such high temperatures.

This invention has been made in light of the above problems. Accordingly, the object of this invention is to provide a chemical strengthening treatment unit for applying chemical strengthening treatment to glass substrates, which is excellent in corrosion resistance as well as heat resistance and is easy to be processed by methods such as welding.

### BRIEF SUMMARY OF THE INVENTION

In order to achieve the above described objective, a unit for applying chemical strengthening treatment to glass substrates for information recording media applications is provided. The unit comprises a holder for holding a plurality of glass substrates and a tank for containing a molten solution of a prescribed salt. In the unit, the glass substrate is chemically strengthened by replacing a part of the ions in the glass substrates with the ions in said molten solution and having ion radius larger than that of the ions in the glass substrate. At least one of the holder and the tank is formed of a nickel alloy.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of preferred embodiments together with accompanying drawings in which:

FIG. 1 shows a cross-sectional view of a chemical strengthening treatment unit for applying a chemical strengthening treatment to glass substrates according to one embodiment of the invention;

FIG. 2 shows a perspective view of a chemical strengthening treatment unit;

FIG. 3 shows a perspective view of a holder, which holds a plurality of glass substrates; and

FIG. 4 shows a perspective view of a cage containing a plurality of holders.

### DETAILED DESCRIPTION OF THE PREFERRED EMBODIMENTS

An embodiment of this invention will be described below in detail with reference to the accompanying drawings.

An apparatus for producing glass substrates includes a surface polishing treatment unit, a chemical strengthening treatment unit, and a rinsing treatment unit. Glass substrates for information recording media applications are obtained by subjecting a glass raw material sheet to a surface polishing treatment, a chemical strengthening treatment, and a rinsing treatment.

Any production processes may be adopted for producing the sheet glass materials as long as they are in the form of a sheet. The production processes include a float method which forms glass to a prescribed thickness on a molten metal; a down draw method which uses gravity; a redraw method which forms a sheet glass from ingot glass; and a method using press molding of a glass dropped on a mold.

The sheet glass materials include soda lime glass containing silicon dioxide (SiO₂), sodium oxide (Na₂O) and calcium oxide (CaO) as main ingredients, aluminosilicate glass containing silicon dioxide, alumina (Al₂O₃), sodium oxide and lithium oxide (Li₂O) as main ingredients, borosilcate glass, lithium oxide-silicon dioxide glass, and lithium oxide-alumina-silicon dioxide glass. Glass for chemical strengthening applications, which contains zirconium oxide (ZrO₂), titanium oxide (TiO₂) and strontium oxide (SrO) as other ingredients can also be used. A sheet glass material is cut into disks (donut shape) using a super hard alloy or diamond. The size of the disks is 2 inches, 2.5 inches or 3 inches, which is adapted to the information recording disks.

The surface polishing treatment includes the steps of polishing the peripheral surfaces of glass substrate, lapping polishing the recording surface, and precision polishing. Generally, the precision polishing is performed as being divided into more than one time step and one by one to enhance the polishing precision.

Rinsing is performed more than once using heated water or performed while irradiating ultrasonic sound.

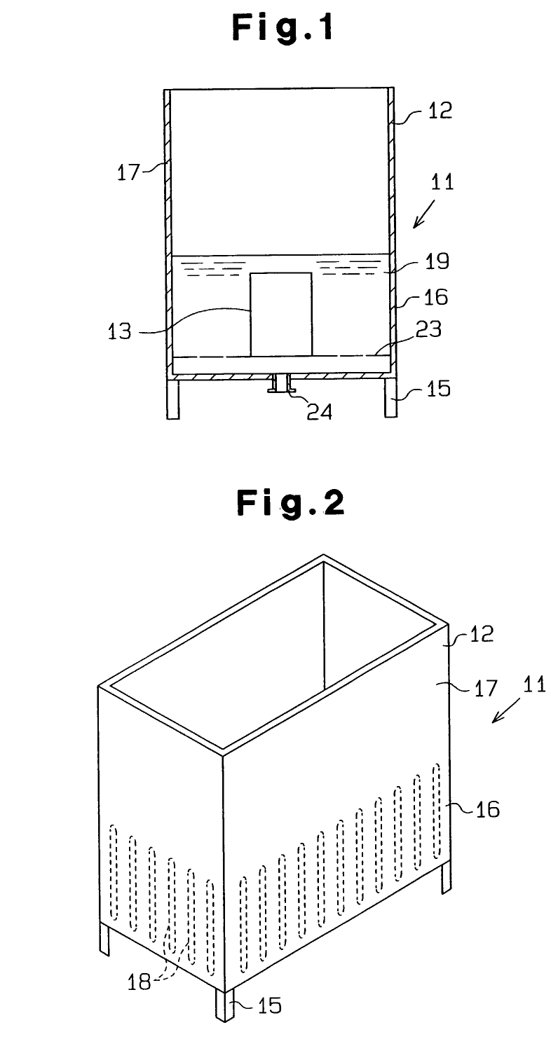

As shown in FIGS. 1 and 2, a tank 12 for the chemical strengthening process contains a molten solution 19 obtained by melting a salt suitable for chemical strengthening. Cages 13 are immersed in the molten solution 19, and each of the cages contains more than one holder 14. A chemical strengthening treatment unit 11 includes the tank 12, holders 14 and cages 13.

The tank 12 includes a tank body 16 and a pre-heating/cooling portion 17 provided at an upper portion of the tank body 16. The tank body takes the form of a square box and has a leg portion 15 on each of its four corners. A plurality of seeds heaters 18 are provided on the side walls and a bottom wall of the tank body 16. These seeds heaters 18 allow the molten solution 19 of a chemical strengthening salt to be heated up to the temperature 50 to 150° C. below the distortion point of glass. The temperature of the molten solution 19 is preferably in a range between 350 and 400° C. Needless to say, the heating temperature is lower than the glass transition point. If the difference between the temperature of the molten salt and the distortion point of glass is more than 150° C., chemical strengthening of the glass substrates is not performed sufficiently. On the other hand, if the difference between the temperature of the molten salt and the distortion point of glass is less than 50° C., it is not preferable because distortion is likely to occur in the glass substrates.

A receiver frame 23 containing the cage 13 is provided at the lower portion of inside the tank body 16. A discharge pipe 24 for discharging the molten salt is provided in the bottom wall of the chemical strengthening tank body 16.

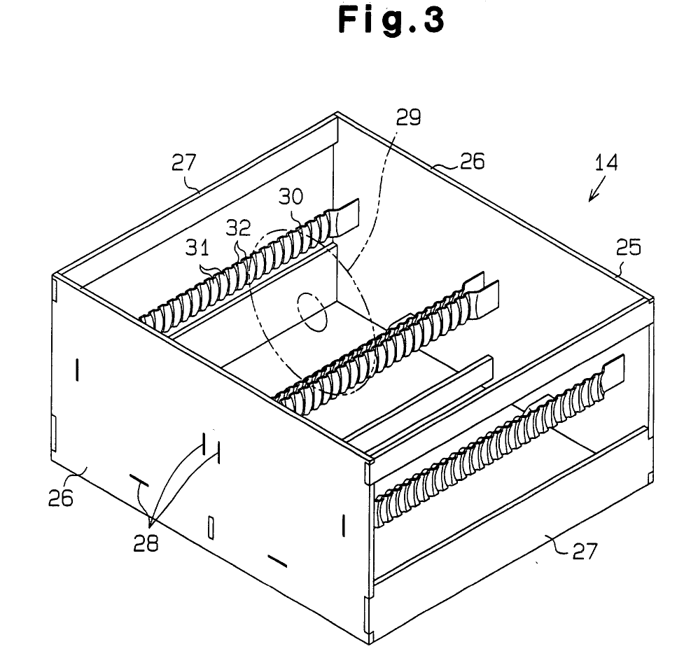

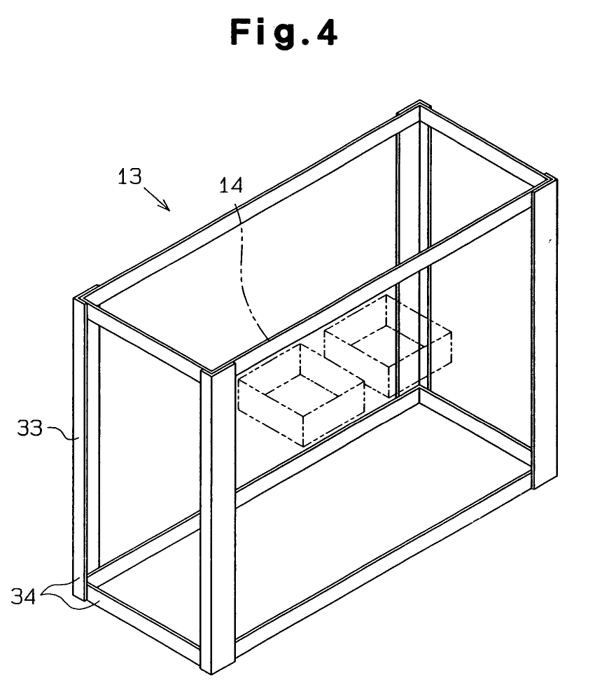

A holder, which holds a plurality of disk-shaped glass substrates, is described next. A holder body 25 constituting the holder 14 includes a pair of sideboards 26 and a plurality of connecting boards 27, as shown in FIG. 3. Each sideboard 26 is in the form of a square plate and is connected to each other by the connecting boards 27 so as to extend in parallel. On each of the sideboards 26, more than one slit 28 is provided in such a manner as to face the slits on the sideboard opposite thereto. Both ends of a supporting member 30, which supports the glass substrate 29, are inserted and engaged in each pair of opposing slits 28.

In this embodiment, a set of three supporting members 30 extending in parallel is provided to support a plurality of glass substrates 29, and two sets of six supporting members 30 are disposed next to each other. Each set of supporting members 30 is disposed between two side plates 26 to support three points of the glass substrate 29 in its outer periphery. While one of the supporting members 30 is not shown in the figures, it is disposed in the neighborhood of the bottom wall of the holder body 25. Each of the other two supporting members 30 is disposed above the supporting member 30 in the neighborhood of the bottom wall, at a predetermined distance separated there from.

A plurality of grooves 32 in the direction of the width of each supporting member 30 is separated by a distance along the length of the supporting member 30. A bulged portion 31 is formed on each supporting member 30 and between adjacent grooves 32 to bulge towards an opposed supporting member 30. Each glass substrate 29 is supported on each set of the three supporting members 30 by engaging a groove 32 in each of the three supporting members 30 at three points on its periphery. Two adjacent glass substrates are prevented from contacting by a bulged portion 31 there between. In this embodiment, for example, when 50 sheets of glass substrates are supported per the set of supporting members 30, 100 sheets of glass substrates are held in the holder 14.

The cage 13 containing the holders 14 is described next. A cage body 33 constituting the cage 13 is formed in the form of frames in a square by joining a plurality of frame bodies 34 extending vertically and horizontally, as shown in FIG. 4. The cage 13 contains the holders 14 side-by-side with a connecting frame, not shown in the figure, extending horizontally. Accordingly, when a single cage 13 contains fourty eight holders 14, it contains four thousand eight hundred glass substrates 29 for each cage.

The cage 13 is immersed in the molten solution 19 contained in the chemical strengthening tank 12, as shown in FIG. 1. In this case, the cage 13 may be immersed in the molten solution 19 after they are pre-heated in the pre-heating/cooling portion 17. The surfaces of the multiple glass substrates 29 held by the holders 14 undergo chemical strengthening treatment by immersing the cage 13 in the molten solution 19 heated to a high temperature for a prescribed period of time.

In one embodiment of this invention, the salt for chemical strengthening includes a powdered mixture of potassium nitrate and sodium nitrate. The salt is heat melted in a melting tank (not shown in the figures) in advance, and the molten solution thereof is stored in the chemical strengthening tank 12. Sodium ions (Na⁺) and lithium ions (Li⁺) in the glass are replaced by the potassium ions (K⁺) or sodium ions (Na⁺) that have ion radius larger than that of the above ions. This allows a compressive stress layer to be formed on the surface of each grass substrate 29, resulting in strengthening the surface of the glass substrate 29.

The glass substrates 29 whose surfaces have undergone chemical strengthening treatment can withstand mechanical impact thereon and thermal shock they receive when a magnetic film is formed on each of the surfaces. Accordingly, the long-term reliability of the hard disks using the glass substrates can be improved.

The holders 14, the cage 13 and the chemical strengthening tank 12 are all formed of alloys containing nickel since such alloys enable them to excel in not only corrosion resistance and heat resistance, but also improve processability in processes such as welding. Of the nickel alloys, the nickel alloys containing 60% by weight or more of nickel, 5 to 30% by weight of chromium and 7% by weight or less of iron are preferable because such alloys improve corrosion resistance, processability and heat resistance in a well-balanced manner. Such nickel alloys include: for example, Inconel™ (15 to 23% by weight of chromium, 10% by weight or less of molybdenum, 2 to 7% by weight of iron, 4% by weight or less of niobium and tantalum in total, and the rest is nickel); Hastelloy B™ (28% by weight of molybdenum, 5% by weight or less of iron, and the rest is nickel); and Hastelloy C™ (16 to 22% by weight of chromium, 13 to 16% by weight of molybdenum, 4% by weight or less of tungsten, 5% by weight or less of iron, and the rest is nickel).

Of the above nickel alloys, Inconel™ is most preferable because it can better improve corrosion resistance, processability and heat resistance. Inconel™ includes: for example, Inconel alloy 625™ (20 to 23% by weight of chromium, 8 to 10% by weight of molybdenum, 2 to 7% by weight of iron, 3.15 to 4.15% by weight of niobium and tantalum in total, and 58% by weight or more of nickel) from Daido Incoalloy Co., Ltd.; and MA 625™ (21.5% by weight of chromium, 8 to 10% by weight of molybdenum, 2 to 7% by weight of iron, 4% by weight or less of niobium and tantalum in total, and 58% by weight or more of nickel) from Mitsubishi Materials Corporation. Inconel™ is excellent in corrosion resistance, which is shown in its resistance to strong acids such as nitric acid and alkali, as well as oxidation resistance compared with stainless steels of which main ingredient is iron, since its main ingredient is nickel. Further, Inconel™ is good in mechanical strength such as tensile strength, bearing force and toughness. Accordingly, in this embodiment, the holders 14, the cages 13 and the chemical strengthening tank 12 are all formed of Inconel™.

After being subjected to the chemical strengthening treatment as described above, the glass substrates 29 are further subjected to precision polishing, rinsing and drying. Afterwards, a primary film, a magnetic film, a protective film and lubricant film are formed on the recording surface of each glass substrate 29 to produce glass substrates 29 for information recording media applications.

A method for the chemical strengthening treatment is next described which uses the above described chemical strengthening treatment unit 11 for applying the chemical strengthening treatment to the glass substrates 29.

As shown in FIG. 2, the holders 14 holding a plurality of the glass substrates 29 contained in the cage 13 are held in a conveyance system not shown in the figure. On the other hand, the chemical strengthening tank 12 is heated by the seeds heater 18 so that the molten salt 19 reaches a temperature of 50° C. to 150° C. below the distortion point of glass. Then, the cage 13 is lowered to the position of the pre-heating/cooling portion 17 of the tank 12 to be pre-heated, and then the cage 13 is further lowered in the tank 12 to be immersed in the molten solution 19 in the tank body 16.

The sodium ions and lithium ions in the glass substrates 29 are replaced by potassium ions or sodium ions with ion radius larger than that of the above ions, respectively, by keeping the glass substrates immersed in the molten solution 19 for several hours, for example, 3 to 5 hours. In particular, the lithium ions in the glass substrates 29 are replaced by potassium ions or sodium ions and the sodium ions in the same are replaced by potassium ions. Thus, a compressive stress layer is formed on the surface of each glass substrate 29 to the depth of about 100 to 200 μm, whereby the surface of each glass substrate 29 is chemically strengthened.

After the application of the chemical strengthening treatment to the glass substrates 29, the cage 13 containing the holders 14 is pulled up and cooled at the pre-heating/cooling portion 17. In the tank 12, such chemical strengthening treatment is repeated on new glass substrates 29. Then the molten solution 19 in the chemical strengthening tank 12 is discharged through the discharge pipe 24.

In the chemical strengthening treatment unit 11 of one embodiment, the holders 14, the cage 13 and the tank 12 are all formed of Inconel™. Thus, even if each piece of equipment is kept in contact with the molten solution including more than one kind of nitrates for a longer period of time, it can fully withstand corrosion. This is attributed to the fact that in nickel alloys such as Inconel™, a close passive layer is formed on the surface thereof and thereby corrosion is prevented from progress. Furthermore, even if the molten solution is at high temperatures, the unit can withstand such high temperatures. In addition, each piece of equipment can be easily processed by, for example, arc welding.

It should be apparent to those skilled in the art that the present invention may be embodied in many other specific forms without departing from the spirit or scope of the invention. Particularly, it should be understood that the invention may be embodied in the following forms.

In the above embodiment, though the holders 14, cages 13 and chemical strengthening tank 12 for chemical strengthening applications are all formed of Inconel™, any number of pieces of equipment may be formed of nickel alloys.

A unit may also be used for applications in which a chemical strengthening tank 12 is formed of thin plates of nickel alloys, and a container or a frame body made of metals such as iron is provided outside the chemical strengthening tank so that it can hold the thin plate. If the unit is constructed in this manner, the amount of nickel alloys used can be saved, resulting in reduction of production costs.

The equipment ancillary to the chemical strengthening treatment unit 11, for example, the discharge pipe 24 on the bottom portion of the chemical strengthening bath 12 and a supply pipe (not shown) for the molten solution 19 may be formed of nickel alloys.

The holders 14 for chemical strengthening may be immersed directly in the molten solution 19 of the chemical strengthening tank 12 instead of being contained in the cage 13.

A U-shaped or V-shaped notch may be provided on the sideboards 26 of the holders 14 or an arbitrarily shaped piercing hole may be provided in the same. In this case, the molten solution 19 can be circulated through openings or holes in the sideboards 26, whereby the chemical strengthening can be performed more efficiently.

Therefore, the present examples and embodiments are to be considered as illustrative and not restrictive and the invention is not to be limited to the details given herein, but may be modified within the scope and equivalence of the appended claims.

What is claimed is:

1. A unit for applying chemical strengthening treatment to glass substrates for information recording media applications, comprising:
a holder for holding said glass substrates having glass substrate ions; and
a tank for containing a molten solution of a prescribed salt having molten solution ions, wherein the molten solution ions have a larger ion radius than an ion radius of the glass substrate ions,
wherein said glass substrates are chemically strengthened by replacing a part of the glass substrate ions with molten solution ions and,
wherein at least one of the holder and the tank is formed of a nickel alloy.

2. The unit according to claim 1, wherein the nickel alloy contains at least 60% by weight of nickel, 5 to 30% by weight of chromium, and up to 7% by weight of iron.

3. The unit according to claim 1, wherein the nickel alloy includes 15 to 23% by weight of chromium, up to 10% by weight of molybdenum, 2 to 7% by weight of iron, up to 4% by weight of niobium and tantalum in total, and balance is nickel.

4. The unit according to claim 1, wherein the glass substrate ions contain sodium ions and lithium ions, and the molten solution ions contain sodium ions and potassium ions.

5. The unit according to claim 1, wherein the molten solution is held at a temperature in a range between about 350 and about 400° C.

6. The unit according to claim 1, said glass substrates are immersed in the molten solution for a time between about 3 and about 5 hours.

7. The unit according to claim 1 further comprising:
a pair of side plates opposing each other;
a plurality of connecting boards connecting the side plates; and
a set of three supporting members extending in a parallel to each other, wherein said three supporting members are held between the pair of side plates, and
wherein said three supporting members support each of the glass substrates in three points in a periphery of said glass substrates.

8. The unit according to claim 7, wherein a plurality of grooves is arranged to extend in a direction of a width of each of said three supporting members and to be separated by a distance along a length of each of said three supporting members, wherein a plurality of bulged portions is formed on each of said three supporting members and between adjacent grooves to bulge toward an opposing supporting member, and wherein each of said glass substrates is being supported on said three supporting members by engaging one of the grooves in each of said three supporting members at said three points.
